(19) United States
(12) Patent Application Publication
(10) Pub. No.: US 2010/0180927 A1
(43) Pub. Date: Jul. 22, 2010

(54) AFFIXING METHOD AND SOLAR DECAL DEVICE USING A THIN FILM PHOTOVOLTAIC AND INTERCONNECT STRUCTURES

(75) Inventor: CHESTER A. FARRIS, III, Yorba Linda, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: STION CORPORATION, San Jose, CA (US)

(21) Appl. No.: 12/510,158

(22) Filed: Jul. 27, 2009

Related U.S. Application Data
(60) Provisional application No. 61/092,371, filed on Aug. 27, 2008.

(51) Int. Cl. H01L 31/045; H01L 31/18

(52) U.S. Cl. 136/245; 438/69; 438/72; 257/E31.119; 257/E31.127

(57) ABSTRACT

A solar device includes a substrate structure having a surface region, a flexible and conformal material comprising a polymer material affixing the surface region. Additionally, the solar device includes one or more solar cells spatially provided by one or more films of materials characterized by a thickness dimension of 25 microns and less and mechanically coupled to the flexible and conformal material, the one or more solar cells having a flexible characteristic that maintains each of the solar cells substantially free from any damage or breakage. The solar device further includes an interconnect structure configured to couple one or more of the solar cells. The interconnect structure includes at least a first contact region and a second contact region within the flexible and conformal material.

### CROSS-REFERENCES TO RELATED APPLICATIONS

This application claims priority to U.S. Provisional Patent Application Ser. No. 61/092,371, filed Aug. 27, 2008, entitled “AFFIXING METHOD AND SOLAR DECAL DEVICE USING A THIN FILM PHOTOVOLTAIC AND INTERCONNECT STRUCTURES” by inventor CHESTER A. FARRIS III commonly assigned and incorporated by reference herein for all purposes.

### STATEMENT AS TO RIGHTS TO INVENTIONS MADE UNDER FEDERALLY SPONSORED RESEARCH AND DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention relates generally to photovoltaic materials and manufacturing methods. More particularly, the present invention provides a conformal solar decal device and method using high efficiency thin film photovoltaic cells. Merely by way of example, the present method and materials include absorber materials made of copper indium disulfide species, copper tin sulfide, iron disulfide, or others for single junction cells or multi junction cells.

From the beginning of time, mankind has been challenged to find ways of harnessing energy. Energy comes in forms such as petrochemical, hydroelectric, nuclear, wind, biomass, solar, and more primitive forms such as wood and coal. Over the past century, modern civilization has relied upon petrochemical energy as an important energy source. Petrochemical energy includes gas and oil. Gas includes lighter forms such as butane and propane, commonly used to heat homes and serve as fuel for cooking Gas also includes gasoline, diesel, and jet fuel, commonly used for transportation purposes. Heavier forms of petrochemicals can also be used to heat homes in some places. Unfortunately, the supply of petrochemical fuel is limited and essentially fixed based upon the amount available on the planet Earth. Additionally, as more people use petroleum products in growing amounts, it is rapidly becoming a scarce resource, which will eventually become depleted over time.

More recently, environmentally clean and renewable source energy has been desired. An example of a clean source of energy is hydroelectric power. Hydroelectric power is derived from electric generators driven by the flow of water produced by dams such as the Hoover Dam in Nevada. The electric power generated is used to power a large portion of the city of Los Angeles in California. Clean and renewable sources of energy also include wind, waves, biomass, and the like. That is, windmills convert wind energy into more useful forms of energy such as electricity. Still other types of clean energy include solar energy. Specific details of solar energy can be found throughout the present background and more particularly below.

Solar energy technology generally converts electromagnetic radiation from the sun to other useful forms of energy. These other forms of energy include thermal energy and electrical power. For electrical power applications, solar cells are often used. Although solar energy is environmentally clean and has been successful to a point, many limitations remain to be resolved before it becomes widely used throughout the world. As an example, one type of solar cell uses crystalline materials, which are derived from semiconductor material ingots. These crystalline materials can be used to fabricate optoelectronic devices that include photovoltaic and photodiode devices that convert electromagnetic radiation to electrical power. However, crystalline materials are often costly and difficult to make on a large scale. Additionally, devices made from such crystalline materials often have low energy conversion efficiencies. Other types of solar cells use “thin film” technology to form a thin film of photosensitive material to be used to convert electromagnetic radiation into electrical power. Similar limitations exist with the use of thin film technology in making solar cells. That is, efficiencies are often poor. Additionally, film reliability is often poor and cannot be used for extensive periods of time in conventional environmental applications. Often, thin films are difficult to mechanically integrate with each other. These and other limitations of these conventional technologies can be found throughout the present specification and more particularly below.

From the above, it is send that improved techniques for manufacturing photovoltaic materials and resulting devices are desired.

### BRIEF SUMMARY OF THE INVENTION

According to the present invention, techniques generally related to photovoltaic materials and manufacturing methods are provided. More particularly, the present invention provides a conformal solar decal device and method using high efficiency thin film photovoltaic cells. Merely by way of example, the present method and materials include absorber materials made of copper indium disulfide species, copper tin sulfide, iron disulfide, or others for single junction cells or multi junction cells.

In a specific embodiment, the present invention provides a solar device. The solar device includes a substrate structure having a surface region and a flexible and conformal material comprising a polymer material affixing the surface region. Additionally, the solar device includes one or more solar cells spatially provided by one or more films of materials characterized by a thickness dimension of 25 microns and less and mechanically coupled to the flexible and conformal material. The one or more solar cells have a flexible characteristic that maintains each of the solar cells substantially free from any damage or breakage. Moreover, the solar device includes an interconnect structure configured to couple one or more of the solar cells. The interconnect structure includes at least a first contact region and a second contact region within the flexible and conformal material.

In another specific embodiment, the present invention provides a solar decal device affixable to a substrate structure. The solar decal device includes a flexible and conformal material comprising a polymer material capable of detachment from a surface region of a transparent handle substrate. Additionally, the solar decal device includes an interface region provided within a vicinity between the surface region and the flexible and conformal material. The solar decal device further includes one or more films of materials coupled to the flexible and conformal material. The one or more films of materials includes an absorber material having a grain size ranging from about 0.5 to about 4 microns. Furthermore, the solar decal device includes one or more solar cells spatially provided by one or more films of materials characterized by a thickness dimension of 25 microns and less and mechanically coupled to the flexible and conformal material. The one or more solar cells have a flexible characteristic that maintains each of the solar cells substantially free from any damage or breakage thereto when the one or more films of materials is subjected to bending. Moreover, the solar decal device includes an interconnect structure configured to couple one or more of the solar cells. The interconnect structure includes at least a first contact region and a second contact region within the flexible and conformal material.

In an alternative embodiment, the present invention provides a method for manufacturing a solar decal device affixable to a substrate structure. The method includes providing a transparent substrate member having a surface region and forming a flexible and conformal material overlying the surface region with a polymer material capable of detachment from the transparent substrate member. Additionally, the method includes patterning the flexible and conformal material to form one or more exposed regions for an interconnect structure and filling the exposed regions with one or more conductive materials. The method further includes forming an interface region within a vicinity between the surface region of the transparent substrate member and the polymer material and forming one or more films of materials with a thickness dimension of 25 microns and less mechanically overlying the flexible and conformal material and coupled to at least the interconnect structure. Furthermore, the method includes forming one or more solar cells spatially provided by the one or more films of materials with a flexible characteristic. The flexible characteristic maintains each of the solar cells substantially free from any damage or breakage thereto when the one or more films of materials is subjected to bending. The method further includes supporting at least the transparent substrate member, the flexible and conformal material, the interface region, and the one or more solar cells to expose a backside region of the transparent substrate member. Moreover, the method includes irradiating the backside region with electromagnetic radiation to selectively release the flexible and conformal material from the surface region of the transparent substrate member to substantially free the one or more solar cells spatially provided by the one or more films of materials mechanically coupled to the flexible and conformal material.

Many benefits are achieved by way of the present invention. For example, the present invention uses starting materials that are commercially available to form a thin film of semiconductor bearing material overlying a suitable substrate member. The thin film of semiconductor bearing material can be further processed to form a semiconductor thin film material of desired characteristics, such as atomic stoichiometry, impurity concentration, carrier concentration, doping, and others. Additionally, the present method uses environmentally friendly materials that are relatively less toxic than other thin-film photovoltaic materials. Depending on the embodiment, one or more of the benefits can be achieved. In a preferred embodiment, the present method uses a conformal and flexible carrier material having an overlying photovoltaic material thereon, which can be applied overlying almost any object of shape and size with a “glove-like” fit. These and other benefits will be described in more detail throughout the present specification and particularly below. Merely by way of example, the present method and materials include absorber materials made of copper indium disulfide species, copper tin sulfide, iron disulfide, or others for single junction cells or multi junction cells.

### BRIEF DESCRIPTION OF THE DRAWINGS

FIG. 1 is a simplified diagram showing a flexible and conformal material formed overlying a transparent substrate according to an embodiment of the present invention;

FIG. 1A is a schematic diagram showing detailed interface region between the flexible and conformal material and surface region of the transparent substrate shown in FIG. 1;

FIG. 2 is a simplified diagram showing one or more films of materials coupled to the flexible and conformal material according to an embodiment of the present invention;

FIG. 3 is a simplified diagram showing one or more solar cells formed in stripes on the transparent substrate according to an embodiment of the present invention;

FIG. 4 is a simplified diagram showing a method of releasing the flexible and conformal material according to an embodiment of the present invention;

FIG. 5A is a simplified diagram showing one solar cell being transferred away from the transparent substrate according to an embodiment of the present invention;

FIG. 5B is a simplified diagram showing a flexible characteristic of solar decal device according to the embodiment of the present invention;

FIGS. 6A-6C are schematic diagrams showing a method of affixing a solar decal device to a substrate structure according to an embodiment of the present invention; and

FIG. 7 is a simplified flowchart illustrating a method for manufacturing a solar decal device affixable to a substrate according to an embodiment of the present invention.

### DETAILED DESCRIPTION OF THE INVENTION

According to the present invention, techniques generally related to photovoltaic materials and manufacturing methods are provided. More particularly, the present invention provides a conformal solar decal device and method using high efficiency thin film photovoltaic cells. Merely by way of example, the present method and materials include absorber materials made of copper indium disulfide species, copper tin sulfide, iron disulfide, or others for single junction cells or multi junction cells.

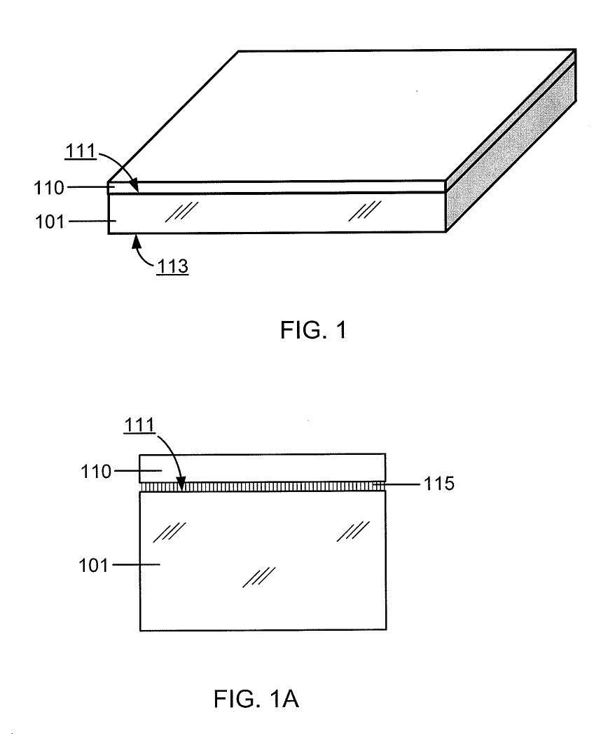

FIG. 1 is a simplified diagram showing a flexible and conformal material formed overlying a transparent substrate according to an embodiment of the present invention. This diagram is merely an example, which should not unduly limit the scope of the claims herein. As shown, a substrate 101 is provided, which has a surface region 111 and a backside region 113. This substrate 101 is used as a handle substrate. In a preferred embodiment, the substrate 101 is an optically transparent solid selected from a dielectric material, such as glass or quartz, a plastic or polymer material, a metal material, or a semiconductor material, or any composites, and layered materials, and the like. The substrate 100 should be at least transparent for certain predetermined operation lasers or other forms of electromagnetic radiation in terms of wavelength ranges, intended for a programmed laser irradiation process applied from the backside region. In certain alternative embodiments, the transparent substrate 100 is a good thermal conductor for performing a thermal process to replace the as-mentioned laser irradiation process. More details on any of these processes for manufacturing a solar decal device will be found throughout this specification and particularly below.

Referring to FIG. 1, a layer of flexible and conformal material 110 is then formed overlying the surface region 111 of the substrate 101. In one embodiment, the flexible and conformal material 110 is a polymer material coating the surface region 111 in a thickness ranging from 1 microns to about 10 microns. The polymer material can be a polymer such as, for example, a polyimide with a predetermined fluidic characteristics so that it can conformally overlay the whole surface region. In another embodiment, the polymer material includes a polyimide material of 20 microns and less. In some embodiments, the polymer material can be also selected from spin on glass, or others. Of course, there can be other variations, modifications, and alternatives.

The coating of the flexible and conformal material 110 can be performed using extrusion, painting, doctor-blade, spin-on, thermal reflow, spray, dipping, electrostatic bonding, and any combination of these techniques and others. In one embodiment, a first layer of the polyimide material is applied directly onto the surface region 111. Subsequently (may adjusting some processing conditions such as temperature, thickness, density, and curing time, etc), a second layer of the polyimide material is applied. In some case, the second layer of the polymer material may be different from the polyimide material used for the first layer. As a result, the first layer, which is correspondingly next to the surface region, is subjecting to a predetermined releasing process. In particular, the technique results a formation of an interface region between the flexible and conformal material 110 and the surface region 111. Depending on the embodiments, the composition of the first layer polymer can be engineered for best releasing performance for either a chemical release mechanism, a photo-reactive release mechanism, or a thermal release mechanism, a photo-plus-thermal release mechanism using laser irradiation from the backside of the transparent substrate member. In an alternative embodiment, this coating technique is also advantageously applied when coating the polymer material over one application substrate member which is for affixing the detached solar cell. More details on this coating process will be described later. Of course, there coating can also be applied as a tape (e.g., polymer film) or other substrate material.

FIG. 1A is a schematic diagram showing detailed structure of an interface region between the flexible and conformal material and surface region of the transparent substrate 101 shown in FIG. 1. This diagram is merely an example, which should not unduly limit the scope of the claims herein. As shown, in a microscopic scale the molecules of the polymer material are only bonded to the molecules of the substrate member material by a plurality of Van der Wal's forces. Naturally, Van der Wal's force is a temporary imbalance of electrons in an atom or molecule in which one end is slightly negative than the other, i.e., an effect of a dipole interaction. Van der Wal's bond is rather weak compared to other types of chemical bonding like hydrogen bond, covalence bond, or metallic bond, but still strong enough to maintain, after a proper curing process, the polymer material intact overlying the surface region without breaking apart. This provides advantage for performing subsequent deposition of photovoltaic materials and formation of one or more solar cells on the flexible and conformal material. More detail description about the forming one or more films of materials over the flexible and conformal material are shown below.

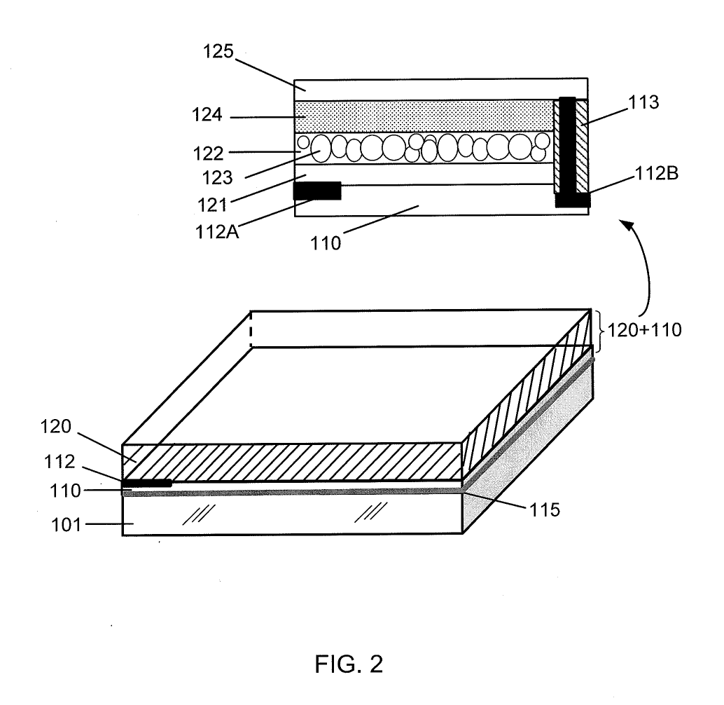

FIG. 2 is a simplified diagram showing one or more films of materials coupled to the flexible and conformal material according to an embodiment of the present invention. This diagram is merely an example, which should not unduly limit the scope of the claims herein. One of ordinary skill in the art would recognize many variations, alternatives, and modifications. As shown, one or more films of materials 120 are mechanically coupled to the flexible and conformal material 110 overlying the surface region 111. In a specific embodiment, the one or more films of materials 120 comprise a multi-layer thin-film photovoltaic materials as shown in an enlarged cross-sectional view. Depending on embodiments, the one or more films of materials 120 includes one or more light absorber layers 122 and one or more window layers 124 that serve as core elements for forming one or more solar cells. In certain embodiments, the one or more films of materials 120 include an interconnect structure 112 that serves as an electrical coupling element for the one or more solar cells. Further details about the thin film structures of the one or more films of materials can be found throughout the specification and more particularly below.

In one implementation, the interconnect structure 112 includes at least a first contact region 112A and a second contact region 112B formed within the flexible and conformal material 110. For example, after coating the flexible and conformal material 110 onto the surface region 111 of the substrate 101, the flexible and conformal material 110 (which can be selected from a polymer material) is patterned to form one or more vias and then filled with one of conductive materials. In one specific embodiment, the first contact region 112A is directly embedded in the flexible and conformal material 110 with a partial exposed portion. The second contact region 112B can be also embedded within the flexible and conformal material 110 but is surrounded by an insulating material 113 which may be further extended above the flexible and conformal material 110. FIG. 2 is merely an example for how to position both the first contact region 112A and the second contact region 112B. There can be many alternatives, variations, and modifications. These contact regions are intended to serve as electrical coupling elements. Usually, conductive material is selected from aluminum, copper, nickel, Alloy 42, silver, gold, molybdenum, or other metal or a conductive dielectric material for forming the contact regions 112A and 112B.

In a specific embodiment, one or more films of materials 120 include a first electrode layer 121 and a second electrode layer 125 to cap the light absorber layer 122 and the window layer 124. Both the first electrode layer 121 and the second electrode layer 125 are made of conductive material characterized by a resistivity less than about 10 ohm-cm. The conductive material can be selected from gold, silver, nickel, platinum, aluminum, tungsten, molybdenum, a combination of these, or an alloy, among others. For example, the conductive material may be deposited using techniques such as sputtering, electroplating, electrochemical deposition and others. In other examples, the first electrode layer 121 and the second electrode layer 125 can be made of an alternative conducting material such as a carbon-based material such as carbon or graphite, or a combination of different conductive materials. Yet alternatively, the first electrode layer 121 and the second electrode layer 125 may be made of a conductive polymer material, an optically transparent material or materials that are light reflecting or light blocking depending on the application. Examples of the optically transparent material can include indium tin oxide (ITO), aluminum doped zinc oxide, fluorine doped tin oxide and others. Of course there can be other variations, modifications, and alternatives.

Referring to the FIG. 2 again, the first electrode layer 121 and the second electrode layer 125 are respectively coupled to the first contact region 112A and the second contact region 112B of the interconnect structure 112. In one embodiment, the first contact region 112A and the second contact region 112B are partially embedded within the flexible and conformal material 110 and can be configured to form an electrical connection with an external conductor or directly couple to another redundant contact region.

Shown in FIG. 2 as a simplified example, one absorber layer 122 overlies the first electrode layer 121, followed by a window layer 124. The absorber layer 122 is of a semiconductor material with P type impurity characteristics which absorbs electromagnetic radiation forming positively charged carriers therein. In a specific embodiment, the absorber layer 122 has a semiconductor bandgap of ranging from about 0.7 eV to about 1.2 eV. In an alternative embodiment, the absorber layer 122 can have a semiconductor bandgap of about 0.5 eV to about 1.2 eV. In a preferred embodiment, the absorber layer 122 can have a bandgap of about 0.5 eV to about 1.0 eV. For example, the absorb layer 122 is made of a composition including cadmium sulfide, a zinc sulfide, zinc selenium (ZnSe), zinc oxide (ZnO), and zinc magnesium oxide (ZnMgO). Microstructurally, the absorber layer 122 includes a plurality of grains 123 having sizes ranging from 0.5 microns to 4 microns. In one embodiment, the absorber layer 122 has a desired thickness that is about the grain size, i.e., about 4-5 microns, depending on the applications. In certain embodiments, the absorber layer 122 can be deposited using techniques of sputtering, spin coating, powder coating, electrochemical deposition, inkjeting, among others, depending on the applications. Of course, there can be other variations, modifications, and alternatives.

Additionally, the window layer 124 is made of a semiconductor material with N⁺ impurity type characteristics. A P-N junction is formed between the N⁺ window layer 124 and the P type absorber layer 122. In a specific implementation, the window layer 124 is characterized by a semiconductor bandgap greater than about 2.5 eV, for example, ranging from 2.5 eV to about 5.5 eV. In a specific embodiment, the window layer 124 comprises a metal chalcogenide semiconductor material and/or other suitable semiconductor material, including a metal sulfide, or a metal oxide, or a metal telluride or a metal selenide material. Alternatively, the window layer 124 can include a metal silicide depending on the application. In another specific embodiment, the window layer 124 can be deposited using techniques such as sputtering, spin coating, doctor blading, powder coating, electrochemical deposition, inkjeting, among others, depending on the application. Of course, there can be other variations, modifications, and alternatives.

In certain embodiments, one or more additional P-N junctions, each including an N⁺ type window layer substantially similar to the window layer 124 overlying a P type absorb layer substantially similar to the absorber layer 122, can be formed over the P-N junction mentioned earlier. In particular, the film compositional structure and electrical-optical characteristics for each P-N junction can be substantially similar. Alternatively, different P-N junction can have different types of photovoltaic materials. The one or more P-N junctions can be coupled to each other via a coupling layer (not explicitly shown). In one embodiment, the coupling layer can be a conductive material, serving as an electrical middle terminal of one or more solar cells. It also serves as a mechanical bonding material between each pair of P-N junctions. In one embodiment, the coupling layer is a multi-layer film, including a glue layer sandwiched between two conductive electrode layers. One conductive electrode layer below is configured to be the upper electric terminal for a first P-N junction and another conductive electrode layer on top serves a lower electric terminal for the second P-N junction over the first P-N junction. Of course there can be other variations, modifications, and alternatives.

Finally referring to the FIG. 2, as shown in the cross-sectional view of the one or more films of materials 120, the second electrode layer 125 overlies the window layer 124 (or the N⁺ type window layer of the up-most P-N junction). Therefore, as an example, structurally the one or more films of materials 120 formed on the flexible and conformal material 110 constitute all the required layers for forming a photovoltaic cell including the absorber layer 122 and the window layer 124 and an interconnect structure 112 with at least the first contact region 112A coupled to the first electrode layer 121 and the second contact region 112B coupled to the second electrode layer 125. Yet alternatively, the one or more films of materials 120 can have different layer structures. For example, one absorber layer can be sandwiched by two window layers. The absorber layer is associated with a first electrode and the two window layers are respectively coupled to two conductive layers which are linked together to become a second electrode. Such layer structures may result in a bifacial solar device with both sides capable of directly or indirectly absorbing sun light. Of course, there are many other alternatives, variations, and modifications in the layer structures of the one or more films of materials for forming solar cells depending on the applications.

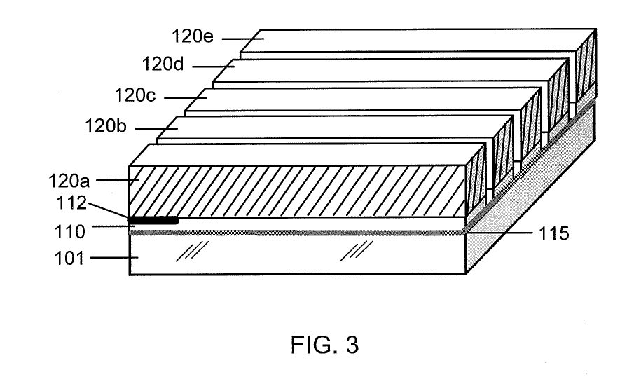

FIG. 3 is a simplified diagram showing one or more solar cells formed in stripes on the transparent substrate according to an embodiment of the present invention. These diagrams are merely examples, which should not unduly limit the scope of the claims herein. One of ordinary skill in the art would recognize many variations, alternatives, and modifications. FIG. 3 shows the one or more films of materials 120 are separated into a plurality of units 120a, 120b, 120c, 120d, and 120e on the transparent substrate 101. In particular, each unit can become a solar cell. For example unit 120a is in a stripe shape of the one or more films of materials 120 including one or more interconnect structure 112 which is laid over a portion of the flexible and conformal material 110. Depending on the embodiment, certain unit separation processes using laser beams can be performed to divide the one or more films of materials 120. More details about the processes for forming the unit cells using laser techniques can be found in a U.S. Patent Application No. 61/03,406, titled “LASER SEPARATION METHOD FOR MANUFACTURE OF UNIT CELLS FOR THIN FILM PHOTOVOLTAIC MATERIALS” and commonly assigned, and hereby incorporated by reference herein. Subsequently each of the separated unit cells can be processed to form one solar cell. In a specific embodiment, each of the one or more solar cells can be capped by a buffer layer (not explicitly shown). The buffer layer serves for blocking the electrode material diffusing into the respective photovoltaic film in any high temperature processing steps. For example, the buffer layer is characterized by a resistivity greater than about 10 kohm-cm and can be provided using a suitable metal oxide material.

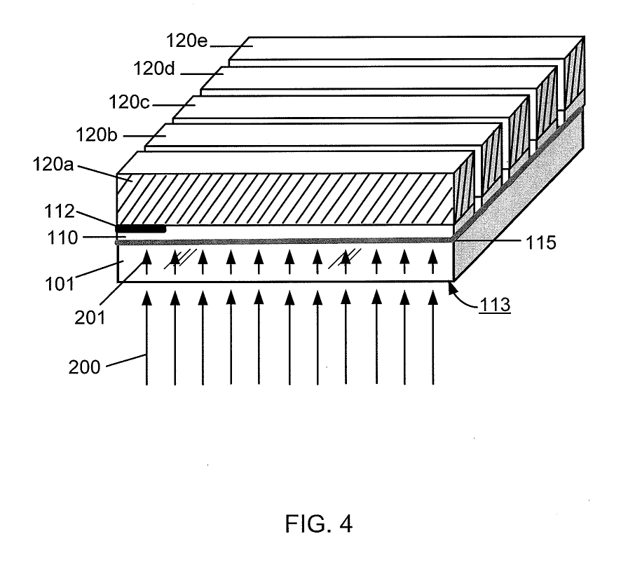

FIG. 4 is a simplified diagram showing a method of releasing the flexible and conformal material according to an embodiment of the present invention. This diagram is merely an example of a plurality of methods to release the flexible and conformal material from the surface region of the handle substrate, which should not unduly limit the scope of the claims herein. One of ordinary skill in the art would recognize many variations, alternatives, and modifications. For example, chemical releasing or dissolving method, thermal releasing method, or mechanical releasing method may be applied and achieve substantially similar result.

In one implementation shown in FIG. 4, electromagnetic radiation 200 is applied from the backside region 113 of the transparent substrate 101. In one embodiment, optical properties of the transparent substrate 101 has been pre-selected by providing a proper material composition, impurity doping, or external coating to achieve a desired transmission characteristics for the applied electromagnetic radiation 200. As the electromagnetic radiation beams 200 pass through the transparent substrate 101 to irradiate the interface region 115, the absorbed energy from the electromagnetic radiation 200 can break the weak Van der Wal's bonds between molecules of the flexible and conformal material 110 and molecules in the surface region 111. In an alternate embodiment, the electromagnetic radiation induced release is substantially a heat-induced releasing of the one or more solar cells with an ability to decompose and/or release. In particular, as mentioned above, the polyimide material in the flexible and conformal material 110 has been pre-selected to be thermally reactive with the corresponding electromagnetic radiation 200 depending on wavelength and absorbing characteristics. In a specific embodiment, it is the first layer (which is directly coupled to the surface region 111) of the polyimide material being reactive with the electromagnetic radiation 200. In another specific embodiment, the time for irradiating the electromagnetic radiation 200 from the backside region 113 can be controlled so that only the first layer of the polyimide material within the flexible and conformal material 110 is reacted. Resulting from the releasing of the flexible and conformal material 110 from the surface region 111, the one or more solar cells 120a, 120b, and so on formed in earlier processes including one or more interconnect structure 112 can be transferred away from a corresponding portion of the transparent substrate 101.

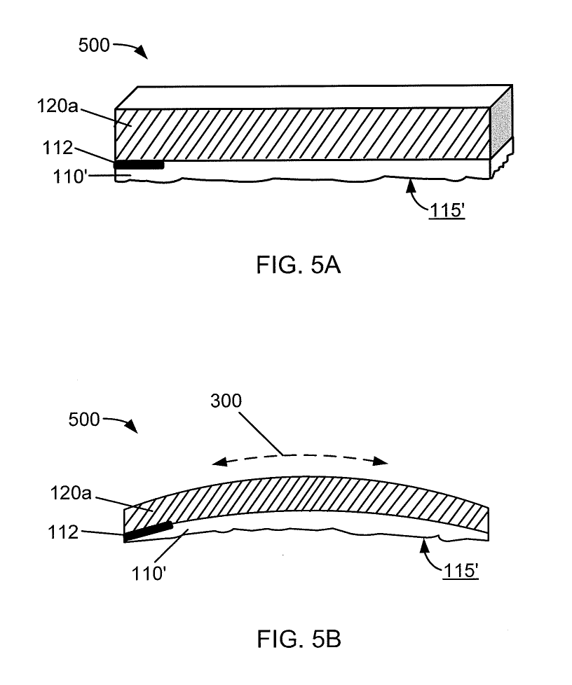

FIG. 5A is a simplified diagram showing one solar cell being transferred away from the transparent substrate according to an embodiment of the present invention. This diagram is merely an example, which should not unduly limit the scope of the claims herein. One of ordinary skill in the art would recognize many variations, alternatives, and modifications. As shown, one solar cell 120a including a remaining portion of flexible and conformal material 110′ becomes a stripe-shaped stand-alone device 500, after transferring away from a corresponding portion of the surface region 111 of the transparent substrate 101. The remaining portion of the flexible and conformal material 110′ has an embedded interconnect structure 112 and has a releasing region 115′ now exposed. In one embodiment, the remaining portion of the flexible and conformal material 110′ serves as a carrier material that can hold the solar cell 120a. This results in a formation of a solar decal device 500 which can be re-applied to various different application substrate members.

FIG. 5B is a simplified diagram showing a flexible characteristic of solar decal device according to the embodiment of the present invention. This diagram is merely an example, which should not unduly limit the scope of the claims herein. One of ordinary skill in the art would recognize many variations, alternatives, and modifications. As shown, the removed solar decal device 500 including a solar cell 120a and the remaining portion of flexible and conformal material 110′ as a whole possesses an intrinsic flexible characteristics. The flexible characteristics of the solar decal device is represented by the whole film subjecting to a bending force 300 which causes the solar cell thereof substantially free from any damage or breakage. For example, bending the whole solar decal device 500 with a radius of curvature down to about 1 mm or greater does not cause any damages to the solar cell therein, but can be other dimensions. In one embodiment, the solar decal device 500 as shown is configured to be re-affixed to a plurality of substrates depending on applications. For example, substrate that can be used for affixing the solar decal device includes a portion of a cell phone, a blue tooth device, a laptop, a personal digital assistant, a wireless device, a sensor device, a camera device, a windshield, a window or other surfaces. In an alternative embodiment, the substrate with the affixed solar decal device can be a portion of an automobile, glass, window, laptop computer, handheld PDA device, clothing, table, housing tile, outdoor furniture, defense and/or space applications, aviation, clothing, housing fixtures such as shades/windows, and other objects, which have shaped or planar features. Of course, there are many alternatives, variations, and modifications.

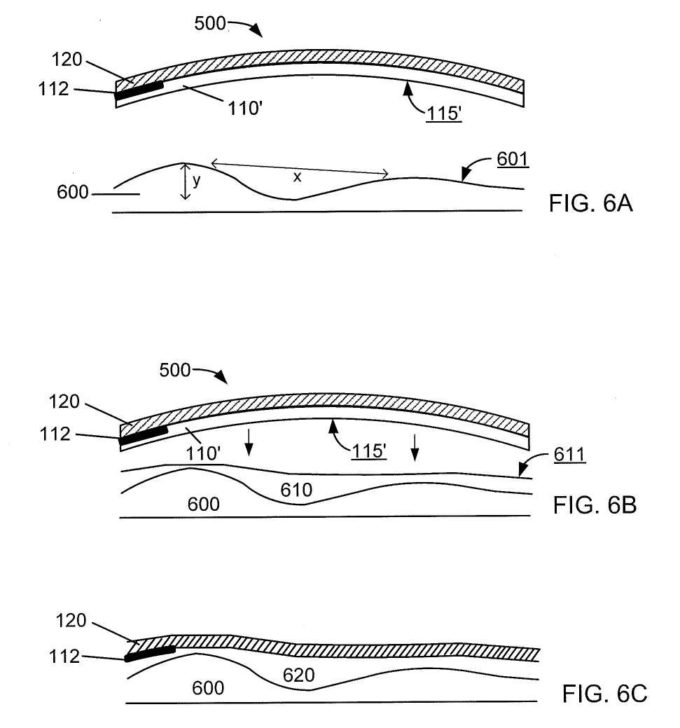

FIGS. 6A-6C are schematic diagrams showing a method of affixing a solar decal device to a substrate structure according to an embodiment of the present invention. This diagram is merely an example, which should not unduly limit the scope of the claims herein. One of ordinary skill in the art would recognize many variations, alternatives, and modifications. As shown in FIG. 6A, a solar decal device 500 including a solar cell 120 having an interconnect structure 112 and a carrier material 110′ is provided. In one embodiment, the solar decal device 500 is made in series of processes described in FIGS. 1-5. The carrier material 110′ is a remaining portion of flexible and conformal material 110, which is a kind of polymer material having a thickness ranging from 1 micron to 10 microns and an exposed surface 115′. The solar cell 120 is made of one or more films of photovoltaic materials including at least a first electrode layer, an absorber layer overlying the first electrode layer, a window layer overlying the absorber layer, and a second electrode layer overlying the window layer. The whole film of the solar cell 120 plus the carrier material 110′ has flexible characteristics, which is represented a bended form shown in FIG. 6A.

Also shown in FIG. 6A, an application substrate member 600 including a portion of surface 601 is provided. The application substrate member 600 can be a portion of a cell phone, a blue tooth device, a laptop, a personal digital assistant, a wireless device, a sensor device, a camera device, a windshield, a window or other surfaces. The surface 601 can be a portion of an automobile, glass, window, laptop computer, handheld PDA device, clothing, table, housing tile, outdoor furniture, defense and/or space applications, aviation, clothing, housing fixtures such as shades/windows, and other objects, which have shaped or planar features. In one embodiment, the surface 601 has certain roughness features that can be represented by at least a vertical spatial scale y and a lateral spatial scale x and corresponding aspect ratio y/x. In one example, the aspect ratio y/x can be as large as desirable depending on applications.

In order to properly affix the solar decal device 500 onto the surface 601, a layer of flexible and conformal material 610 is applied first. In one embodiment, the layer of flexible and conformal material 610 comprises a polyimide material having a thickness of about 20 microns. The polyimide material has a predetermined fluidic characteristics that can overlays the whole surface 601 in conformal fashion. For example, a spatial feature as large as desirable in the surface 601 can be covered. As a result, a polymer surface 611 becomes much smoother than original substrate surface 601. In another embodiment, the coated flexible and conformal material 610 is configured to bond with the carrier material 110′ associated with the solar decal device 500. FIG. 6B shows the solar decal device 500 is to be applied onto the flexible and conformal material 610 coated application substrate 600. The exposed surface 115′ of the carrier material 110′ is about to engage with the polymer surface 611. In one embodiment, both the carrier material 110′ and the pre-coated flexible and conformal material 610 are substantially the same polymer material. Under a certain thermal treatment process, both the both the carrier material 110′ and the pre-coated flexible and conformal material 610 are substantially merged into a single layer of flexible and conformal material 620. In one implementation, the single layer of the flexible and conformal material 620 can conformally overlay one or more spatial features on the application substrate having an irregular shape of feature sizes of about four times a thickness of the one or more films of materials for forming the solar cell 120. As shown in FIG. 6C, the solar decal device 500 has been affixed onto the application substrate 600 mediated with a flexible and conformal material 620 therebetween. As pointed out earlier, the solar decal device 500 conformally applied on the application substrate 600 comprises a flexible characteristics with substantially free of any damage of solar cell therein.

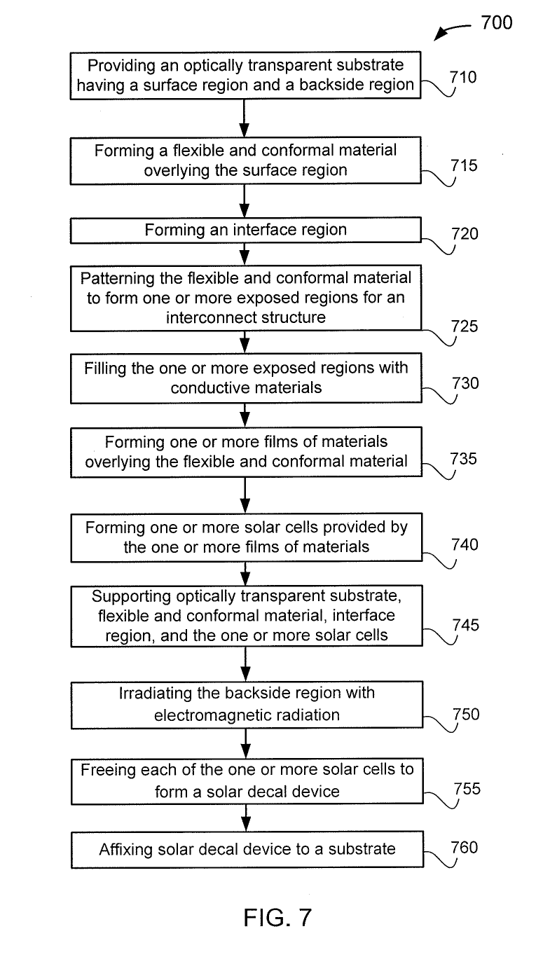

FIG. 7 is a simplified flowchart illustrating a method for manufacturing a solar decal device affixable to a substrate according to an embodiment of the present invention. This diagram is merely an example, which should not unduly limit the scope of the claims herein. The method 700 includes the following processes:

1. Process 710 for providing an optical transparent substrate having a surface region and a backside region;

2. Process 715 for forming a flexible and conformal material overlying the surface region;

3. Process 720 for forming an interface region;

4. Process 725 for patterning the flexible and conformal material to form one or more exposed regions for an interconnect structure;

5. Process 730 for filling the one or more exposed regions with conductive materials;

6. Process 735 for forming one or more films of materials overlying the flexible and conformal material;

7. Process 740 for forming one or more solar cells provided by the one or more films of materials;

8. Process 745 for supporting optically transparent substrate, the flexible and conformal material, interface region, and the one or more solar cells;

9. Process 750 for irradiating the backside region with electromagnetic radiation;

10. Process 755 for freeing the one or more solar cells to form a solar decal device; and

11. Process 760 for affixing the solar decal device to a substrate.

The above sequence of processes provides a method for manufacturing a solar decal device affixable to a substrate structure according to an embodiment of the present invention. Other alternatives can also be provided where some processes are added, one or more processes can be removed, or one or more processes are provided in a different sequence without departing from the scope of the claims herein. Further details of the method can be found throughout the present specification and more particularly below.

At Process 710, an optically transparent substrate is provided. In one embodiment, the optically transparent substrate includes a substrate material selected from a dielectric material, such as glass or quartz, a polymer or plastic material, a metal material, a semiconductor, a composite, or layered material, and the like. In another embodiment, the optically transparent substrate is transparent to an electromagnetic radiation with a predetermined wavelength range. For example, the electromagnetic radiation is a laser beam with wavelength ranging from 400 nm to 700 nm, but can be others. In one implementation, the optically transparent substrate includes a surface region and a backside region, which is substantially the same as the handle substrate 101 shown in FIGS. 1 through 4.

At Process 715, a flexible and conformal material is formed overlying the optically transparent substrate. In one embodiment, the flexible and conformal material is a polymer material with a thickness ranging from 1 micron to 10 microns. In a specific embodiment, the flexible and conformal material is a polyimide material. In one implementation, FIG. 1 has shown an execution of the Process 715 with the flexible and conformal material 110 overlying the transparent substrate 101.

At Process 720, an interface region is formed between the flexible and conformal material and the surface region of the transparent substrate. In particular, the interface region is referred to a spatial area with hetero-molecular interactions between two different types of materials. Unlike inside region within the polymer material or inside region within the substrate material where homo-molecular interaction is dominated by strong covalence bond or hydrogen bond, the interface region between the polymer material and the substrate material is characterized by relatively weak Van der Wal's forces specifically between the molecules of the polymer material and molecules of the substrate material. During the application process, the polymer material of the flexible and conformal material forms a plurality of Van der Wal's forces that are just strong enough to hold onto the transparent substrate and serve as a new base for forming a thin film solar cell. More importantly, this interface region advantageously facilitates a detachment process performed later for forming a solar decal device.

At Process 725, the flexible and conformal material is patterned to form one or more exposed regions for an interconnect structure. In one implementation, the one or more exposed regions includes one or more vias. Depending on the application, at least a first via has a proper position, depth, width, and length. At least a second via also is formed in the Process 725 with a position separated from the first via. This process can be performed using photo-processing, masking, etching, or others. In one embodiment, the Process 715 and the Process 725 may have different orders when executing one or more steps. For example, an etching process may be followed by another polymer deposition process or vise versa.

At Process 730, the method 700 includes filling the one or more exposed regions with a conductive material. In particular, this process is to introduce actual material into the patterned vias to form the actual interconnect structure. The conductive material can be selected from aluminum, copper, nickel, Alloy 42, silver, gold, molybdenum, or other metal or a conductive dielectric material which is deposited specifically to fill the vias. In one implementation, at least the first via is filled to form a first contact region. The first contact region has at least a portion of area that is exposed as part of an surface area of the flexible and conformal material, intending for directly coupling with an electrode layer overlying said surface area. In addition, the second via can be filled with the conductive material to form a second contact region. In one implementation, the second contact region is also embedded within the flexible and conformal material but with an extension structure above the surface area, intending for coupling with another electrode layer. Specifically, the second contact region may be covered or surrounded by an insulating material to prevent it from electrically shorting the second contact region with other layer structures.

At Process 735, one or more films of materials are formed overlying the flexible and conformal material. In particular, the one or more films of materials are thin film photovoltaic materials configured to form one or more P-N junctions between at least two conducting electrode layers. For example, the one or more films of materials includes a first electrode layer overlying the flexible and conformal material. The first electrode layer also makes a direct coupling with the first contact region formed in Process 730. Over the first electrode layer an absorber layer is formed and followed by a window layer to have a P-N junction. Above that, a second electrode layer is formed overlying the window layer. The second electrode layer is configured to make electrical coupling with the second contact region formed at Process 730. In an embodiment, the Process 725, 730 and 735 may be executed in different orders when performing some steps. For example, forming the absorber layer and window layer may be before forming the insulation material for the second contact region or vise versa. In one specific implementation, the one or more films of materials are the films 120 including the first electrode layer 121, the absorber layer 122, the window layer 124, the second electrode layer 125, and the first contact region as well as the second contact region forming the interconnect structure 112, according to the illustration of FIG. 2. Depending the applications, the substrate can be treated as superstrate, the first or second electrode layer identity can be reversed, and the absorber layer and window layer also are disposed in opposite position while at least one electrode layer over the window layer for receiving sun light should have optical transparent characteristics.

At Process 740, one or more solar cells are formed from the one or more films of materials. In one embodiment, the one or more films of materials overlying the flexible and conformal material are separated into one or more units using a laser separation technique developed by the inventor. In another embodiment, the one or more solar cells are characterized by a thin film with a thickness dimension of 25 microns and less. More details about the laser separation processes for forming a plurality of unit cells can be found in a U.S. Patent Application No. 61/033,406, titled “LASER SEPARATION METHOD FOR MANUFACTURE OF UNIT CELLS FOR THIN FILM PHOTOVOLTAIC MATERIALS” and commonly assigned, and hereby incorporated by reference herein. In one implementation, each unit cell is formed in a stripe shape on a portion of the surface region of the transparent substrate. Each unit cell includes a solar cell overlying a portion of flexible and conformal material.

At Process 745, the method 700 includes supporting the optically transparent substrate, flexible and conformal material, interface region, and the one or more solar cells as a whole work piece. In particular, the process includes disposing the whole work piece at a process station where the optically transparent substrate is properly supported so that the backside region is fully exposed to a laser source. The laser source is selected with predetermined pulse rate, wavelength, power range, and beam characteristic that accommodate the optically transparent substrate and capable of interacting with the polymer material at the interface region between the flexible and conformal material and the surface region.

At Process 750, the method 700 further includes irradiating the backside region with an electromagnetic radiation. In specific implementation, the electromagnetic radiation is a laser beam generated by the laser source within the process station. The laser beam is scanned from a portion of the backside region to another portion and transmitted through the optically transparent substrate to reach the interface region. In certain embodiment, the laser beam is a pulsed laser in nature. In other embodiment, the laser beam can be CW laser.

At Process 755, the one or more solar cells are freed from the surface region of the transparent substrate. As the laser energy is absorbed by the molecules within the interface region, the relatively weak Van der Wal's bonds between hetero-molecules at the interface region are substantially broken so that the polymer material becomes detachable. As the laser power and exposure time is properly selected, the film structure and associated device functionality of the one or more solar cells provided by the one or more films of materials above the flexible and conformal material are still substantially free of any damages. In a specific embodiment, for the one or more solar cells have been pre-formatted into stripe shapes, the one or more solar cells can be peeled off one-by-one in stripe shape from one portion of the surface region to another portion. As each solar cell is released from the optically transparent substrate, a portion of flexible and conformal material is still tightly attached, serving as a carrier material to hold the thin film solar cell. In one implementation, the transferred solar cells carried by the remaining portion of flexible and conformal material becomes a solar decal device that is also flexible to some degrees. The flexible solar decal device can be shipped stand-alone and capable of affixing to a variety of application substrate. The flexible characteristic is represented by bending the whole device to a certain radius of curvature which causes substantially free damages or breakage of the solar cells thereto.

At Process 760, the method 700 includes affixing the solar decal device to an application substrate structure. In particular, the application substrate structure is pre-coated with a matching polymer material that is flexible and conformal to corresponding surface features with certain aspect ratio. In one embodiment, the aspect ratio can be as large as desired. In certain implementation, the size of the spatial features on the application substrate structure can be four times larger than the thickness of the thin film solar cell to be affixed. In another embodiment, certain thermal process or chemical process is performed to ensure the bonding between the remaining flexible and conformal material associated with the solar decal device and the matching polymer material. Finally, the solar decal device is affixed with the application substrate, mediated with a flexible and conformal material in between so that the solar cells can be attached to surfaces of the application substrate structure which might be rough to some degrees. For example, the application substrate structure includes a portion of a cell phone, a blue tooth device, a laptop, a personal digital assistant, a wireless device, a sensor device, a camera device, a windshield, a window or other surfaces. In another aspect, the application substrate surface can be a portion of an automobile, glass, window, laptop computer, handheld PDA device, clothing, table, housing tile, outdoor furniture, and other shaped or planar objects, including any of those noted herein, and outside of this specification.

Although the above has been described in terms of specific embodiments, one of ordinary skill in the art would recognize other variations, modifications, and alternatives. As an example, a cell can be made of cadmium telluride (CdTe) material that is a crystalline compound formed from cadmium and tellurium. In a specific embodiment, the CdTe has a zinc blend (cubic) crystal structure. As an example, the CdTe crystalline form is a direct bandgap semiconductor. Depending upon the embodiment, the CdTe is sandwiched with cadmium sulfide to form a P-N junction photovoltaic solar cell. In a specific embodiment, a multi junction cell including an upper cell and lower cell. As an example, the upper cell or any cell can made according to HIGH EFFICIENCY PHOTOVOLTAIC CELL AND MANUFACTURING METHOD listed under U.S. Patent Application No. 61/059,253 (Attorney Docket No. 026335-002500US), commonly assigned, and hereby incorporated for all purposes. In one or more embodiments, the top cell comprises an absorber layer selected from CuInS₂, SnS, Cu(In₂Al)S₂, Cu(In₁₋ₓ), Alₓ)S₂, Cu(In, Ga)S₂, or Cu(In₁₋ₓ, Ga)S₂ or other suitable materials. In other specific embodiments, the bottom cell may comprise an absorber layer selected from CIGS, Cu₂SnS₃, FeS₂, or Ge or others. Additionally, the lower cell can be made of an alternative material that receives any traversing energy through the upper cell. As an example, the lower cell can be made of a suitable material such as silicon, polysilicon, CIGS, and other materials. Of course, there can be other variations, modifications, and alternatives.

It is understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A solar device comprising:
a substrate structure having a surface region;
a flexible and conformal material comprising a polymer material affixing the surface region;
one or more solar cells spatially provided by one or more films of materials characterized by a thickness dimension of 25 microns and less and mechanically coupled to the flexible and conformal material, the one or more solar cells having a flexible characteristic, wherein the flexible characteristic maintains each of the solar cells substantially free from any damage or breakage; and
an interconnect structure configured to couple one or more of the solar cells, the interconnect structure including at least a first contact region and a second contact region within the flexible and conformal material.

2. The solar device of claim 1 wherein the flexible and conformal material plus the one or more solar cells has been chemically released, dissolved, laser released, photo-reactively released, mechanically released, or thermally released from a handle substrate.

3. The solar device of claim 1 wherein the substrate structure is a portion of a cell phone, a blue tooth device, a laptop, a personal digital assistant, a wireless device, a sensor device, a camera device, a windshield, a window or other surfaces.

4. The solar device of claim 1 wherein the substrate structure is a portion of an automobile, glass, window, laptop computer, handheld PDA device, clothing, table, housing tile, outdoor furniture, space application, and defense application.

5. The solar device of claim 1 wherein the flexible and conformal material is selected from a polyimide material of 20 microns and less.

6. The solar device of claim 1 wherein the flexible and conformal material comprises a first layer of the polymer material overlying a second layer of the polymer material.

7. The solar device of claim 1 wherein the one or more films of materials comprise a first electrode layer overlying the flexible and conformal material, a absorber layer overlying the first electrode layer, a window layer overlying the absorber layer, and a second electrode layer overlying the transparent conductive oxide layer.

8. The solar device of claim 7 wherein the absorber layer comprises a composition including copper indium disulfide or indium gallium disulfide.

9. The solar device of claim 7 wherein the window layer comprises one of compositions of cadmium sulfide, zinc sulfide, zinc selenium (ZnSe), zinc oxide (ZnO), and zinc magnesium oxide (ZnMgO).

10. The solar device of claim 7 wherein the first electrode layer directly couples to the first contact region and the second electrode layer directly couples to the second contact region, the second contact region being electrically insulated from the first electrode layer.

11. The solar device of claim 1 wherein the interconnect structure is made of a material selected from aluminum, copper, nickel, Alloy 42, silver, gold, molybdenum, or other metal or conductive dielectric materials.

12. A solar decal device affixable to a substrate structure, the solar decal device comprising:
a flexible and conformal material comprising a polymer material capable of detachment from a surface region of a transparent handle substrate;
an interface region provided within a vicinity between the surface region and the flexible and conformal material;
one or more films of materials coupled to the flexible and conformal material, the one or more films of materials including an absorber material having a grain size ranging from about 0.5 to about 4 microns;
one or more solar cells spatially provided by one or more films of materials characterized by a thickness dimension of 25 microns and less and mechanically coupled to the flexible and conformal material, the one or more solar cells having a flexible characteristic, wherein the flexible characteristic maintains each of the solar cells substantially free from any damage or breakage thereto when the one or more films of materials is subjected to bending; and
an interconnect structure configured to couple one or more of the solar cells, the interconnect structure including at least a first contact region and a second contact region within the flexible and conformal material.

13. The solar decal device of claim 12 wherein the transparent handle substrate is selected from glass, quartz, metal, semiconductor, or plastic.

14. The solar decal device of claim 12 wherein the transparent handle substrate is optically transparent to a laser irradiation.

15. The solar decal device of claim 14 wherein the polymer material is configured to absorb thermal energy from the laser irradiation.

16. The solar decal device of claim 14 wherein the flexible and conformal material is configured to be selectively released by laser irradiation.

17. The solar decal device of claim 16 wherein the flexible and conformal material after releasing from the transparent handle substrate ranges from about 1 micron to about 10 microns.

18. The solar decal device of claim 12 wherein the flexible and conformal material acts as a carrier material to hold the one or more solar cells.

19. The solar decal device of claim 18 further is configured to be conformally overlaid on the substrate structure comprising a portion of an automobile, glass, window, laptop computer, handheld PDA device, clothing, table, housing tile, or outdoor furniture.

20. The solar decal device of claim 19 wherein the substrate structure comprises one or more spatial features having an aspect ratio of about a predetermined amount conformally overlaid by a layer of flexible and conformal material.

21. The solar decal device of claim 20 wherein the one or more spatial features have an irregular shape of feature sizes of about four times a thickness of the one or more films of materials.

22. The solar decal device of claim 12 wherein one or more films of materials comprises a first electrode layer, an absorber layer overlying the electrode layer, a window layer overlying the absorber layer, and a second electrode layer overlying the window layer.

23. The solar decal device of claim 22 wherein the first electrode layer directly couples to the first contact region and the second electrode layer directly couples to the second contact region, the second contact region being electrically insulated from the first electrode layer.

24. The solar decal device of claim 12 the absorber material of the one or more films of materials comprises a thickness about the same as the grain size.

25. The solar decal device of claim 12 wherein the interconnect structure is made of a material selected from aluminum, copper, nickel, Alloy 42, silver, gold, molybdenum, or other metal or conductive dielectric materials.

26. The solar decal device of claim 12 wherein the interface region comprises a plurality of Van der Wal's forces between molecules of the polymer material and molecules of the transparent handle substrate.

27. The solar decal device of claim 12 wherein each of the one or more solar cells comprises stripe shape arranged on and to be released from one portion of the transparent handle substrate.

28. A method for manufacturing a solar decal device affixable to a substrate structure, the method comprising:
providing a transparent substrate member having a surface region;
forming a flexible and conformal material overlying the surface region with a polymer material capable of detachment from the transparent substrate member;
patterning the flexible and conformal material to form one or more exposed regions for an interconnect structure;
filling the exposed regions with one or more conductive materials;
forming an interface region within a vicinity between the surface region of the transparent substrate member and the polymer material;
forming one or more films of materials with a thickness dimension of 25 microns and less mechanically overlying the flexible and conformal material and coupled to at least the interconnect structure;
forming one or more solar cells spatially provided by the one or more films of materials with a flexible characteristic, wherein the flexible characteristic maintains each of the solar cells substantially free from any damage or breakage thereto when the one or more films of materials is subjected to bending;
supporting at least the transparent substrate member, the flexible and conformal material, the interface region, and the one or more solar cells to expose a backside region of the transparent substrate member; and
irradiating the backside region with electromagnetic radiation to selectively release the flexible and conformal material from the surface region of the transparent substrate member to substantially free the one or more solar cells spatially provided by the one or more films of materials mechanically coupled to the flexible and conformal material.

29. The method of claim 28 wherein providing a transparent substrate member comprises using a substrate material selected from glass, quartz, metal, semiconductor or plastic.

30. The method of claim 29 wherein the substrate material is optically transparent to the electromagnetic radiation.

31. The method of claim 28 wherein forming the flexible and conformal material comprises coating the surface region with the polymer material ranging from about 1 micron to about 10 microns.

32. The method of claim 28 wherein each of the one or more solar cells comprises a stripe shape arranged on and to be released from one portion of the transparent substrate member.

33. The method of claim 32 further comprises affixing the stripe shape solar cell onto a substrate structure pre-applied with a layer of the flexible and conformal material.

34. The method of claim 33 wherein the substrate structure comprises a portion of an automobile, glass, window, laptop computer, handheld PDA device, clothing, table, housing tile, outdoor furniture, and or shaped object.

35. The method of claim 28 wherein filling the exposed regions with one or more conductive materials comprises forming at least a first contact region and a second contact region embedded within the flexible and conformal materials.

36. The method of claim 35 wherein the one or more conductive materials comprise aluminum, copper, nickel, Alloy 42, silver, gold, molybdenum, or other metal or conductive dielectric materials.

37. The method of claim 35 wherein forming one or more films of materials mechanically overlying the flexible and conformal material and coupled to at least the interconnect structure comprises sequentially forming a first electrode layer, an absorber layer, a window layer, and a second electrode layer, the first electrode layer being coupled to the first contact region, the second electrode layer being coupled to the second contact region.

38. The method of claim 37 wherein the absorber layer comprises a sun-light adsorbing material with a grain size ranging from about 0.5 to about 4 microns and a film thickness about the grain size.

39. The method of claim 28 wherein forming an interface region comprises bonding molecules of the flexible and conformal material to molecules of the surface region with a plurality of Van der Wal's forces.
